(19) United States
(12) Patent Application Publication
(10) Pub. No.: US 2026/0066657 A1
(43) Pub. Date: Mar. 5, 2026

(54) ELECTRICAL POWER SUPPLY SYSTEMS AND RELATED METHODS

(71) Applicant: ABB SCHWEIZ AG, Baden (CH)

(72) Inventors: Abhinav Patni, Raleigh, NC (US); Sheng Zhong, Hillsborough, NC (US); Alexandre Santerre, Saint-Jean sur Richelieu (CA); Chantal Fleury, Longueuil (CA); Matthew Hetrich, Cary, NC (US); Huangjie Gong, Raleigh, NC (US); Marc Turcotte, Laval (CA)

(21) Appl. No.: 18/822,933

(22) Filed: Sep. 3, 2024

(51) Int. Cl. H02J 3/00; G01R 22/06

(52) U.S. Cl. CPC H02J 3/0073; G01R 22/065; H02J 2105/42; H02J 2105/51

(57) ABSTRACT

Electrical power supply systems may include a housing separate from a meter socket, an input disconnect in the housing configured to receive electrical power from the meter socket, an auxiliary disconnect in the housing configured to receive electrical power from the input disconnect and to provide the electrical power to an auxiliary device, and a main electrical output in the housing configured to receive electrical power from the input disconnect and to provide the electrical power to a disconnect panel. Various other related systems and methods are also disclosed.

### BACKGROUND

The increasing popularity of electric vehicles (EVs) or other auxiliary electrical devices has led to a rise in energy use in homes. This higher power usage, including from homes with EV chargers, can benefit from electrical power data monitoring. Such monitoring systems may be helpful in comprehending energy use patterns and improving overall consumption. The data obtained can offer homeowners useful details about their energy use, allowing them to better control power and balance between everyday electricity needs and auxiliary demands (e.g., EV charging demands). Higher energy bills can often result from increased electrical loads, making power data monitoring a helpful consideration for homeowners who have auxiliary electrical needs. These monitoring systems can also support utility companies in handling grid load more efficiently, helping avoid power outages or fluctuations that could disrupt service.

### BRIEF SUMMARY

In some aspects, the techniques described herein relate to an electrical power supply system, including: a housing separate from a meter socket; an input disconnect in the housing configured to receive electrical power from the meter socket; an auxiliary disconnect in the housing configured to receive electrical power from the input disconnect and to provide the electrical power to an auxiliary device; and a main electrical output in the housing configured to receive electrical power from the input disconnect and to provide the electrical power to a disconnect panel.

In some aspects, the techniques described herein relate to a system, further including an auxiliary electrical output configured to receive electrical power from the auxiliary disconnect and to provide the electrical power to the auxiliary device.

In some aspects, the techniques described herein relate to a system, further including an electrical monitoring device in the housing, the electrical monitoring device configured to sense electrical current passing through at least one of the main electrical output or the auxiliary electrical output.

In some aspects, the techniques described herein relate to a system, wherein the electrical monitoring device includes at least one of: an input current sensor coupled to the input disconnect to sense electrical current passing into the housing; a main current sensor coupled to the main electrical output to sense electrical current passing through the main electrical output; or an auxiliary current sensor coupled to the auxiliary electrical output to sense electrical current passing through the auxiliary electrical output.

In some aspects, the techniques described herein relate to a system, wherein the main electrical output includes a main conductor and the auxiliary electrical output includes an auxiliary conductor.

In some aspects, the techniques described herein relate to a system, further including at least one auxiliary lug that splits a conductive path from the input disconnect into the main electrical output and the auxiliary electrical output.

In some aspects, the techniques described herein relate to a system, further including a neutral lug in the housing, the neutral lug configured to be coupled to a neutral wire.

In some aspects, the techniques described herein relate to a system, further including a ground lug in the housing, the ground lug configured to be coupled to a ground wire.

In some aspects, the techniques described herein relate to a system, wherein the auxiliary device includes one or more of: an electric vehicle charging station; an electric vehicle; a pump; an air conditioning unit; a heater; or a refrigerator.

In some aspects, the techniques described herein relate to a system, wherein the disconnect panel includes one or more of: a residential breaker panel; a commercial breaker panel; a fuse box; a fusible switch box; or a protective relay panel.

In some aspects, the techniques described herein relate to a system, wherein: the input disconnect includes an input breaker; and the auxiliary disconnect includes an auxiliary breaker.

In some aspects, the techniques described herein relate to an electrical power supply system, including: a meter socket including a socket for connecting a power meter; a housing separate from the meter socket; an input disconnect in the housing; an inlet branch in the housing for providing electrical power from the meter socket to the input disconnect; a main outlet branch in the housing for selectively transmitting electrical power from the input disconnect to a main disconnect panel; an auxiliary outlet branch in the housing for selectively transmitting electrical power from the input disconnect to an auxiliary device; and at least one auxiliary disconnect in the housing and coupled to the auxiliary outlet branch, the at least one auxiliary disconnect configured to selectively transmit electrical power respectively to at least one auxiliary device.

In some aspects, the techniques described herein relate to a system, wherein the input disconnect includes at least one of: an input fuse; an input breaker; an input fusible switch; or an input protective relay.

In some aspects, the techniques described herein relate to a system, wherein the at least one auxiliary disconnect includes at least one of: an auxiliary fuse; an auxiliary breaker; an auxiliary fusible switch; or an auxiliary protective relay.

In some aspects, the techniques described herein relate to a system, further including an electrical monitoring device in the housing, the electrical monitoring device including: at least one input current sensor configured to sense electrical current passing from the meter socket to the input disconnect along the inlet branch; at least one main current sensor configured to sense electrical current passing to the main disconnect panel from the input disconnect along the main outlet branch; and at least one auxiliary current sensor configured to sense electrical current passing to the at least one auxiliary device from the at least one auxiliary disconnect through the auxiliary outlet branch.

In some aspects, the techniques described herein relate to a system, further including a communication module for communicating information based on signals from the at least one input current sensor, at least one main current sensor, and at least one auxiliary current sensor to a user device.

In some aspects, the techniques described herein relate to a system, wherein the at least one auxiliary disconnect includes at two or more auxiliary disconnects configured to selectively transmit electrical power respectively to two or more auxiliary devices.

In some aspects, the techniques described herein relate to a system, wherein the housing is mounted adjacent to and along a same wall as the meter socket.

In some aspects, the techniques described herein relate to a method of forming a power supply system, the method including: positioning an input disconnect in a housing, the input disconnect configured to receive electrical power from a power meter; and positioning an auxiliary disconnect in the housing, the auxiliary disconnect configured to selectively receive electrical power from the input disconnect and to selectively provide the electrical power to an auxiliary device.

In some aspects, the techniques described herein relate to a method, further including positioning an electrical monitoring device in the housing, the electrical monitoring device including a main current sensor for sensing electrical current passing from the input disconnect to a main disconnect panel and an auxiliary current sensor for sensing electrical current passing from the auxiliary disconnect to an auxiliary device.

### BRIEF DESCRIPTION OF THE DRAWINGS

FIG. 1 is a schematic view of a power supply system that optionally includes an electrical monitoring device, according to at least one embodiment of the present disclosure.

FIG. 2 is a schematic view of a power supply system that includes a housing separate from a meter socket, according to at least one additional embodiment of the present disclosure.

FIG. 3 is a schematic diagram of a power supply system, according to at least one additional embodiment of the present disclosure.

FIG. 4 is a schematic diagram of a power supply system that is connected to multiple auxiliary devices, according to at least one additional embodiment of the present disclosure.

FIG. 5 is a schematic view of a power supply system, according to at least one further embodiment of the present disclosure.

FIG. 6 is a flow diagram illustrating a method of forming power supply system, according to at least one embodiment of the present disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

The present disclosure provides detailed descriptions of electrical power supply systems. As will be explained in greater detail below, embodiments of the present disclosure may include an auxiliary connection device including a housing that is separate from a meter socket. The meter socket may include a socket for connecting a power meter. The meter socket may be lockable or otherwise access-limited. An input disconnect (e.g., breaker, fuse, switch, etc.) in the housing may be configured to receive electrical power from the meter socket. An auxiliary disconnect may also be in the housing. The auxiliary disconnect may be configured to receive electrical power from the input disconnect and to provide the electrical power to an auxiliary device (e.g., an electric vehicle (EV) charging station, an electric vehicle, a pump, an air conditioning unit, a heater, a refrigerator, etc.). A main electrical output in the housing may be configured to receive electrical power from the input disconnect and to provide the electrical power to a disconnect panel (e.g., a residential breaker panel, a commercial breaker panel, a fuse panel, etc.). Examples of such systems may be useful to facilitate installation of one of more auxiliary devices in an electrical system. Such systems may also enable electrical monitoring of the electrical system, including monitoring of power going to the disconnect panel and/or to the one or more auxiliary devices, regardless of the type of auxiliary devices.

Features from any of the embodiments described herein may be used in combination with one another in accordance with the general principles described herein. These and other embodiments, features, and advantages will be more fully understood upon reading the following detailed description in conjunction with the accompanying drawings and claims.

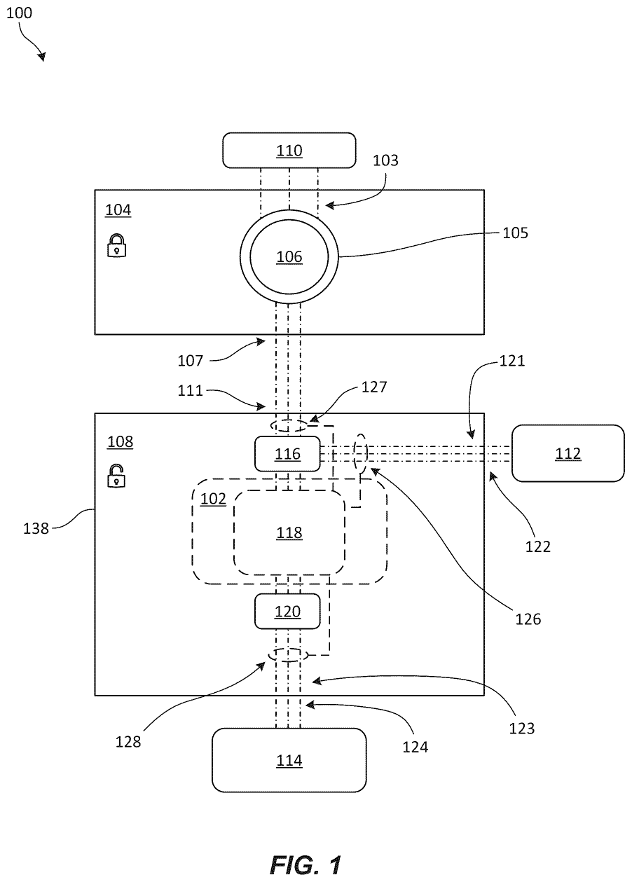

FIG. 1 is a schematic view of a power supply system 100 that optionally includes an electrical monitoring device 102 (shown in dashed lines), according to at least one embodiment of the present disclosure. The power supply system 100 may include a meter socket 104 and an auxiliary connection device 108. The auxiliary connection device 108 may include a housing 138 that is separate from the meter socket 104.

The meter socket 104 may include a first input 103 for receiving power from a utility grid 110. A socket 105 may be positioned in the meter socket 104 for connecting to a power meter 106. A first output 107 of the meter socket 104 may provide electrical power out of the meter socket 104 to the auxiliary connection device 108, such as through one or more suitable electrical conductors (e.g., busbars, wires, cables, etc.).

The housing 138 of the auxiliary connection device 108 may house the electrical monitoring device 102 (if present), an input disconnect 116 for receiving electrical power from the meter socket 104 (e.g., through an inlet branch to the input disconnect 116), and an auxiliary disconnect 120 for receiving electrical power from the input disconnect 116 (e.g., through an auxiliary outlet branch from the input disconnect 116). A second input 111 of the auxiliary connection device 108 may receive the electrical power from the first output 107 of the meter socket 104 and into the auxiliary connection device 108.

In some examples, relational terms, such as “first,” “second,” “main,” “auxiliary,” etc., may be used for clarity and convenience in understanding the disclosure and accompanying drawings and do not connote or depend on any specific preference, orientation, or order, except where the context clearly indicates otherwise.

A main electrical output 121 of the auxiliary connection device 108 may receive electrical power from the input disconnect 116 (e.g., through a main outlet branch from the input disconnect 116) and may provide the electrical power to a disconnect panel 112 (e.g., a residential breaker panel, a commercial breaker panel, a fuse box, a fusible switch box, a protective relay panel, etc.).

An auxiliary electrical output 123 of the auxiliary connection device 108 may receive electrical power from the input disconnect 116 (e.g., through the auxiliary outlet branch from the input disconnect 116) and may provide electrical power to at least one auxiliary device 114. In FIG. 1, a single auxiliary device 114 is illustrated. However, in additional embodiments, the power supply system 100 may be used to supply power to multiple auxiliary devices 114, such as through multiple respective auxiliary electrical outputs 123 and multiple respective auxiliary disconnects 120.

The power supply system 100 may receive electrical power from the utility grid 110 for providing power to the disconnect panel 112 and/or to the auxiliary device(s) 114.

In some embodiments, the meter socket 104 may be lockable or otherwise access-limited (e.g., for access only by personnel authorized by a power company), such as for securing the meter socket 104 from unauthorized access to inhibit tampering and/or theft of electrical power and for safety. The auxiliary connection device 108 may be accessible by a user and/or electrician (e.g., without authorization by a power company), such as for installation of one or more auxiliary devices 114, resetting of the input disconnect 116 and/or auxiliary disconnect 120, maintenance, modification, inspection, etc.

In the example shown in FIG. 1, the utility grid 110 may provide a single-phase (e.g., three-wire) alternating current (AC) power supply including at least a hot wire and a neutral wire. In additional examples, the utility grid 110 may be a two-wire AC power supply or a four wire AC power supply. The AC power supply from the utility grid 110 may be a single-phase (e.g., split-phase) AC power supply or a three-phase AC power supply.

Power from the utility grid 110 may pass through the power meter 106 for measuring total electrical power usage through the disconnect panel 112 and the auxiliary device 114. An output of the meter socket 104 may be operably connected to a power input of the auxiliary connection device 108, such as via suitable conductors (e.g., cables, wires, traces, etc.). Conductors are represented in FIG. 1 by dash-dot lines.

A main power connection 122 may be capable of transmitting electrical power from the input disconnect 116 to the disconnect panel 112. An auxiliary power connection 124 may be capable of transmitting electrical power from the auxiliary disconnect 120 to and/or from the auxiliary device 114.

The input disconnect 116 may be positioned between the power meter 106 and the electrical monitoring device 102 (if present) and between the power meter 106 and the disconnect panel 112. By way of example and not limitation, the input disconnect 116 may be or include an input breaker, an input fuse, an input fusible switch, an input protective relay, etc. In some embodiments, the input disconnect 116 may be rated with a sufficiently high amperage to supply full power to both the disconnect panel 112 and the auxiliary device 114. In other words, the current rating of the input disconnect 116 may be at least as high as the combination of the disconnect panel 112 rating and of the auxiliary device 114 rating, such as to reduce instances of the input disconnect 116 inadvertently opening and halting service to both the disconnect panel 112 and to the auxiliary device 114 during normal operation. In additional examples, the current rating of the input disconnect 116 may be the same as the current rating of the disconnect panel 112.

The auxiliary disconnect 120 may be positioned between the electrical monitoring device 102 (if present) and the auxiliary device 114. By way of example and not limitation, the auxiliary disconnect 120 may be or include an auxiliary breaker, an auxiliary fuse, an auxiliary fusible switch, an auxiliary protective relay, etc. The auxiliary disconnect 120 may be configured to interrupt service to or from the auxiliary device 114 for installation or maintenance, in case of a fault (e.g., short-circuit) in the auxiliary device 114, for installation or maintenance of the electrical monitoring device 102, etc.

The electrical monitoring device 102, if present, may include a data collection and control module 118. As will be explained further below, the data collection and control module 118 may be configured to sense at least one first electrical characteristic of the main power connection 122 and/or at least one second electrical characteristic of the auxiliary power connection 124. For example, the electrical monitoring device 102 may include at least one input sensor 127 for sensing the total power input from meter socket 104, at least one main sensor 126 for sensing the first electrical characteristic of the main power connection 122 and/or at least one auxiliary sensor 128 for sensing the second electrical characteristic of the auxiliary power connection 124. By way of example and not limitation, each of the at least one input sensor, at least one main sensor 126, and at least one auxiliary sensor 128 may be in the form of an inductive sensor, a current shunt sensor, a Hall effect-based sensor, a fluxgate sensor, and/or a Rogowski principle-based sensor (e.g., a Rogowski coil sensor).

As illustrated in FIG. 1 in dashed lines, the electrical monitoring device 102 may include any one or more of the input sensor 127, main sensor 126, and auxiliary sensor 128. For example, the main sensor 126 is illustrated along the main power connection 122 between the input disconnect 116 and the disconnect panel 112 to measure, for example, current flowing to the disconnect panel 112 (e.g., a main residential breaker panel). Alternatively or additionally, the input sensor 127 may be positioned between the power meter 106 and the input disconnect 116 to measure, for example, a total current flowing to the input disconnect 116 and ultimately to both the disconnect panel 112 and the auxiliary device 114. Alternatively or additionally, the electrical monitoring device 102 may include the at least one auxiliary sensor 128 along the auxiliary power connection 124 between the input disconnect 116 and the auxiliary device 114 to measure, for example, current flowing to the auxiliary device 114. In additional embodiments, a sensor may be coupled to a conductor in another location than is shown in FIG. 1. Accordingly, the electrical monitoring device 102 may include any one of the input sensor 127, main sensor 126, and auxiliary sensor 128, any combination thereof, and/or one or more additional sensors.

The data collection and control module 118 may be in the form of a printed circuit board (PCB) that includes at least an analog-to-digital converter for processing signals from the input sensor 127, the main sensor 126, and the auxiliary sensor 128. The data collection and control module 118 may also include a control module for controlling power to the auxiliary device 114 and/or a communication module for communicating information based on the signals to a user device or other recipient. One or more of these components of the data collection and control module 118 may be implemented via one or more microprocessors, signal processing components, transistors, transceivers, etc.

In some embodiments, the first electrical characteristic and the second electrical characteristic may include current and/or voltage, and/or a characteristic derived from current and/or voltage (e.g., power). The data collection and control module 118 may also be configured to communicate the first and second electrical characteristic, or information based on the first and second electrical characteristic, to a user device or other recipient. For example, the main sensor 126 may be or include a first current sensor for sensing an electrical current in the main power connection 122 and the auxiliary sensor 128 may be or include a second current sensor for sensing an electrical current in the auxiliary power connection 124. Responsive to levels of the first and second electrical characteristic and/or to a command from the user device or other recipient, the data collection and control module 118 may disconnect at least some power to the auxiliary device 114 and/or reconnect power to the auxiliary device 114.

The auxiliary device 114 may be one or more devices that use electrical power. Examples of the auxiliary device 114 include an electric vehicle (EV) charging station, an EV, a pump, an air conditioning unit, a heater, a refrigerator, etc. Other devices that draw electrical power may also be considered auxiliary devices 114. In additional embodiments of the present disclosure, the auxiliary device 114 may generate electricity, and the auxiliary power connection 124 may operate as an input to the power supply system 100, such as for providing electrical power to the disconnect panel 112. For example, the auxiliary device 114 may be or include a wind turbine, a water turbine, a thermal power generator, a gas generator, a solar panel, etc. Accordingly, the at least one auxiliary sensor 128 can, in some embodiments, be used to obtain power data regardless of the direction that electrical current flows in the auxiliary power connection 124.

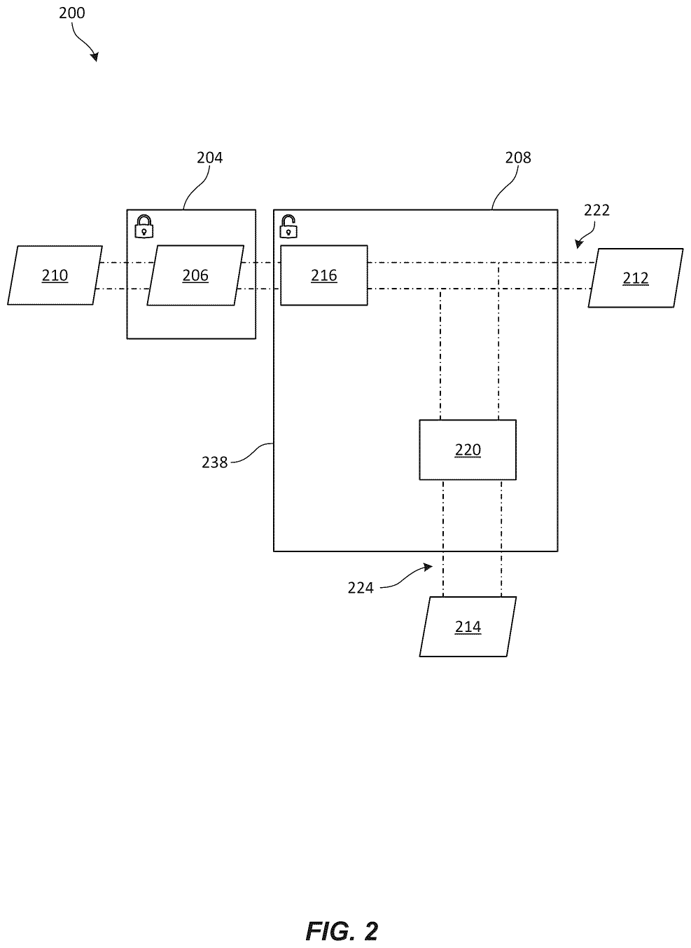

FIG. 2 is a schematic view of a power supply system 200 that includes a housing 238 separate from a meter socket 204, according to at least one additional embodiment of the present disclosure.

In some respects, the power supply system 200 of FIG. 2 may be similar to the power supply system 100 illustrated in FIG. 1. For example, the power supply system 200 of FIG. 2 may include a power meter 206 in the meter socket 204 that receives electrical power from a utility grid 210, an input disconnect 216 in the auxiliary connection device 208 that receives electrical power from the meter socket 204, and an auxiliary disconnect 220 in the auxiliary connection device 208 that receives electrical power from the input disconnect 216. A disconnect panel 212 (e.g., a residential breaker panel, a commercial breaker panel, a fuse box, a fusible switch box, a protective relay panel, etc.) may also receive power from the input disconnect 216, such as through a main power connection 222. At least one auxiliary device 214 may receive power from the input disconnect 216, such as through the auxiliary disconnect 220 and through an auxiliary power connection 224.

The meter socket 204 may be lockable or otherwise access-limited (e.g., for access only by personnel authorized by a power company), such as to inhibit tampering and/or theft of electrical power and for safety. The auxiliary connection device 208 may be accessible by a user and/or electrician (e.g., without authorization by a power company), such as for the installation of one or more auxiliary devices 214, resetting of the input disconnect 216 and/or auxiliary disconnect 220, maintenance, modification, inspection, etc.

Referring to FIG. 2, the meter socket 204 containing the power meter 206 may be physically separate from the housing 238 of the auxiliary connection device 208. In some examples, the housing 238 may be mounted adjacent to (e.g., along a same wall as) the meter socket 204. In additional examples, the housing 238 may be mounted remotely from the meter socket 204, such as adjacent to the auxiliary device 214 or adjacent to the disconnect panel 212.

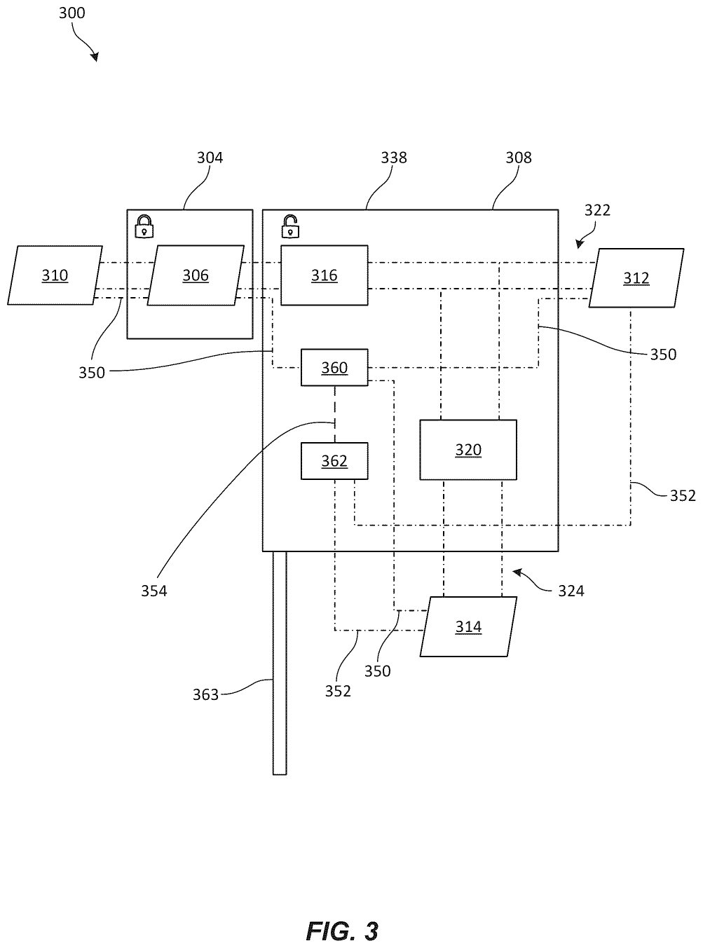

FIG. 3 is a schematic view of a power supply system 300, according to at least one additional embodiment of the present disclosure.

In some respects, the power supply system 300 may be similar to the power supply system 200 of FIG. 2. For example, the power supply system 300 of FIG. 3 may include a power meter 306 in a meter socket 304 that receives electrical power from a utility grid 310, an input disconnect 316 in an auxiliary connection device 308 that receives electrical power from the meter socket 304, and an auxiliary disconnect 320 in the auxiliary connection device 308 that receives electrical power from the input disconnect 316. A disconnect panel 312 (e.g., a residential breaker panel, a commercial breaker panel, a fuse box, a fusible switch box, a protective relay panel, etc.) may also receive power from the input disconnect 316, such as through a main power connection 322. At least one auxiliary device 314 may receive power from the input disconnect 316, such as through the auxiliary disconnect 320 and through an auxiliary power connection 324. The auxiliary connection device 308 may include a housing 338 that is separate from the meter socket 304.

The meter socket 304 may be lockable or otherwise access-limited (e.g., for access only by personnel authorized by a power company). The auxiliary connection device 308 may be accessible by a user and/or electrician (e.g., without authorization by a power company).

The system 300 of FIG. 3 also includes a neutral line 350 and a ground line 352 suitable for electrical components that employ or require a ground and/or neutral electrical signal. For example, a neutral lug 360 in the auxiliary connection device 308 may be operably coupled to the neutral line 350 from the utility grid 310 and from the power meter 306. The neutral line 350 may separate into one or more neutral branches to provide a neutral signal to various components of the power supply system 300, such as to the disconnect panel 312 and to the auxiliary device 314. A ground lug 362 in the auxiliary connection device 308 may be grounded, such as through the housing 338 and/or a ground rod 363. The ground line 352 may act as a ground return path for various components of the power supply system 300, such as for the disconnect panel 312 and the auxiliary device 314, ultimately terminated to the ground lug 362.

The neutral lug 360, and therefore the neutral line 350, may be tied to ground, such as through a system bonding jumper 354 between the neutral lug 360 and the ground lug 362. Additionally or alternatively, a neutral lug may be positioned in the meter socket 304, and the neutral line 350 may be tied to ground through a system bonding jumper between the neutral lug in the meter socket 304 and the neutral lug 362, the ground lug 360, and/or the ground rod 363 in or connected to the housing 338.

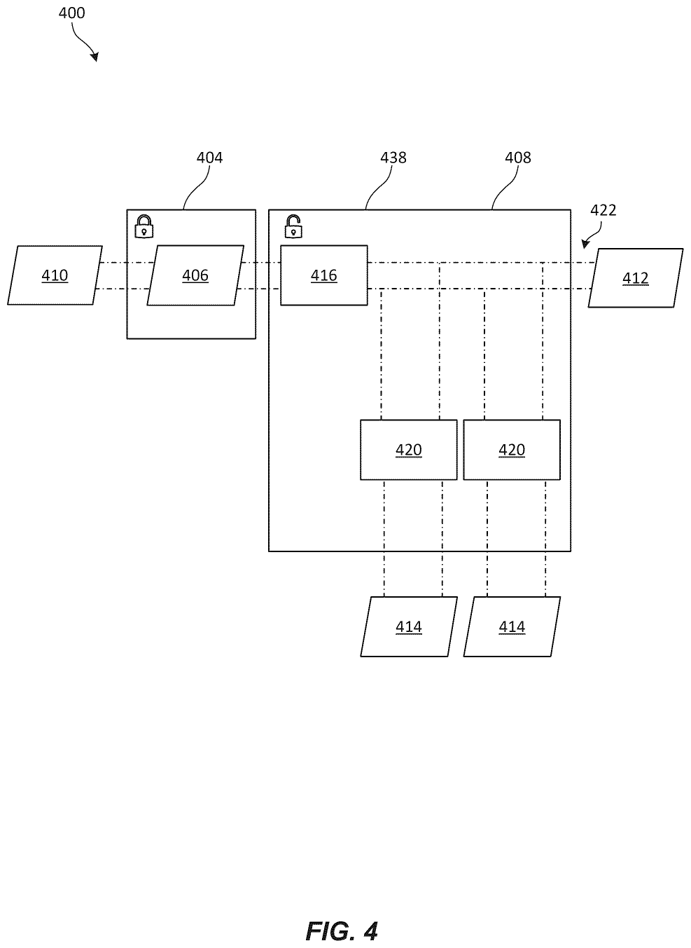

FIG. 4 is a schematic view of a power supply system 400 that is connected to multiple auxiliary devices 414, according to at least one additional embodiment of the present disclosure.

In some respects, the power supply system 400 of FIG. 4 is similar to the power supply system 200 of FIG. 2. For example, the power supply system 400 of FIG. 4 may include a meter socket 404 and an auxiliary connection device 308 that includes a housing 438 separate from the meter socket 404. The system 400 may include a power meter 406 in the meter socket 404 that receives electrical power from a utility grid 410 and an input disconnect 416 in the auxiliary connection device 408 that receives electrical power from the meter socket 404. A disconnect panel 412 may receive power from the input disconnect 416, such as through a main power connection 422.

The meter socket 404 may be lockable or otherwise access-limited (e.g., for access only by personnel authorized by a power company). The auxiliary connection device 408 may be accessible by a user and/or electrician (e.g., without authorization by a power company).

As shown in FIG. 4, the system 400 may be configured to supply electrical power to two or more auxiliary devices 414. For example, the system 400 may include two or more auxiliary disconnects 420 in the auxiliary connection device 408 that receive electrical power from the input disconnect 416. The two or more auxiliary devices 414 may be operably coupled to the respective two or more auxiliary disconnects 420. Accordingly, embodiments of the present disclosure may be capable of use with one auxiliary device 414, two auxiliary devices 414, or more than two auxiliary devices 414.

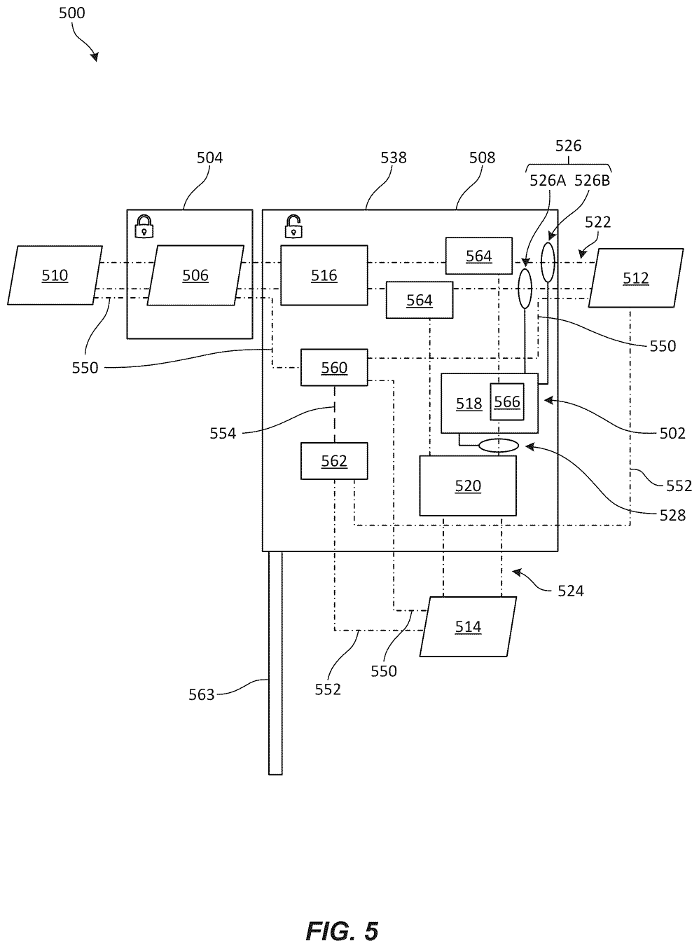

FIG. 5 is a schematic view of a power supply system 500, according to at least one further embodiment of the present disclosure.

In some respects, the power supply system 500 may be similar to the power supply system 300 of FIG. 3. For example, the power supply system 500 of FIG. 5 may include a power meter 506 in a meter socket 504 that receives electrical power from a utility grid 510, an input disconnect 516 in an auxiliary connection device 508 that receives electrical power from the meter socket 504, and an auxiliary disconnect 520 in the auxiliary connection device 508 that receives electrical power from the input disconnect 516. A disconnect panel 512 may also receive power from the input disconnect 516, such as through a main power connection 522. At least one auxiliary device 514 may receive power from the input disconnect 516, such as through the auxiliary disconnect 520 and through an auxiliary power connection 524. The auxiliary connection device 508 may include or be housed in a housing 538 that is separate from the meter socket 504.

The meter socket 504 may be lockable or otherwise access-limited (e.g., for access only by personnel authorized by a power company). The auxiliary connection device 508 may be accessible by a user and/or electrician (e.g., without authorization by a power company).

The system 500 of FIG. 5 also includes a neutral line 550 and a ground line 552 suitable for electrical components that employ or require a ground and/or neutral electrical connection. For example, a neutral lug 560 in the auxiliary connection device 508 may be operably coupled to the neutral line 550 from the utility grid 510 and from the power meter 506. The neutral line 550 may separate into one or more neutral branches to provide a neutral signal to various components of the power supply system 500, such as to the disconnect panel 512 and to the auxiliary device 514. A ground lug 562 in the auxiliary connection device 508 may be grounded, such as through the housing 538 and/or a ground rod 563. The ground line 552 may act as a ground return path for various components of the power supply system 500, such as for the disconnect panel 512 and the auxiliary device 514, ultimately terminated to the ground lug 562.

The neutral lug 560, and therefore the neutral line 550, may be tied to ground, such as through a system bonding jumper 554 between the neutral lug 560 and the ground lug 562. Additionally or alternatively, a neutral lug may be positioned in the meter socket 504, and the neutral line 550 may be tied to ground through a system bonding jumper between the neutral lug in the meter socket 504 and the neutral lug 562, the ground lug 560, and/or the ground rod 563 in or connected to the housing 538.

In some embodiments, the power supply system 500 may include one or more auxiliary lugs 564, which may be used to split a conductive path (e.g., one or more hot lines) from the input disconnect 516 into the main power connection 522 and the auxiliary power connection 524.

As shown in FIG. 5, the auxiliary connection device 508 of the power supply system 500 may include an electrical monitoring device 502, which may include a data collection and control module 518. The data collection and control module 518 may include an auxiliary relay 566 for controlling whether electrical power, or a portion thereof, is supplied to the auxiliary device 514. The data collection and control module 518 may receive data representative of at least one electrical characteristic (e.g., current, voltage, etc.) from one or more main sensors 526 (e.g., current sensor(s)) coupled to a main power connection 522 and one or more auxiliary sensors 528 (e.g., current sensor(s)) coupled to the auxiliary power connection 524. The auxiliary relay 566 may be positioned along the auxiliary power connection 524, such as along one hot line of the auxiliary power connection 524. In additional embodiments, two auxiliary relays 566 may be positioned along two respective hot lines of the auxiliary power connection 524.

For example, the one or more main sensors 526 may include a first main sensor 526A and a second main sensor 526B. In the example illustrated in FIG. 5, the main power connection 522 may be configured for split-phase power. The first main sensor 526A may be coupled to a hot wire associated with a first AC phase and the second main sensor 526B may be coupled to a hot wire associated with a second AC phase. In additional embodiments, a single main sensor 526 or more than two main sensors 526 may be employed. The first main sensor 526A and the second main sensor 526B may be configured to sense one or more electrical characteristics (e.g., current, voltage) of the main power connection 522.

Only one auxiliary sensor 528 is illustrated in FIG. 5. However, the present disclosure is not so limited. In additional embodiments, multiple auxiliary sensors 528 may be used. The one or more auxiliary sensors 528 may be coupled to the auxiliary power connection 524, such as a hot wire of the auxiliary power connection 524.

The main sensors 526 and the auxiliary sensor 528 are illustrated in FIG. 5 in particular locations relative to other components of the power supply system 500. However, the present disclosure is not so limited. For example, the main sensor 526 may be positioned between the input disconnect 516 and the one or more auxiliary lugs 564 or between the power meter 506 and the input disconnect 516. Likewise, the one or more auxiliary sensors 528 may be located between the one or more auxiliary lugs 564 and the data collection and control module 518 or between the auxiliary disconnect 520 and the auxiliary device 514. In further embodiments, one or more of the one or more main sensors 526 and the one or more auxiliary sensors 528 may be absent, and/or one or more additional main sensors 526 or auxiliary sensors 528 may be present in the power supply system 500.

The data collection and control module 518 may be configured to control the operation of the auxiliary device 514 based on data from the one or more main sensors 526 and/or from the one or more auxiliary sensors 528. For example, the data collection and control module 518 may include an auxiliary relay 566 configured to selectively open or close to respectively stop or allow power to flow to the auxiliary device 514.

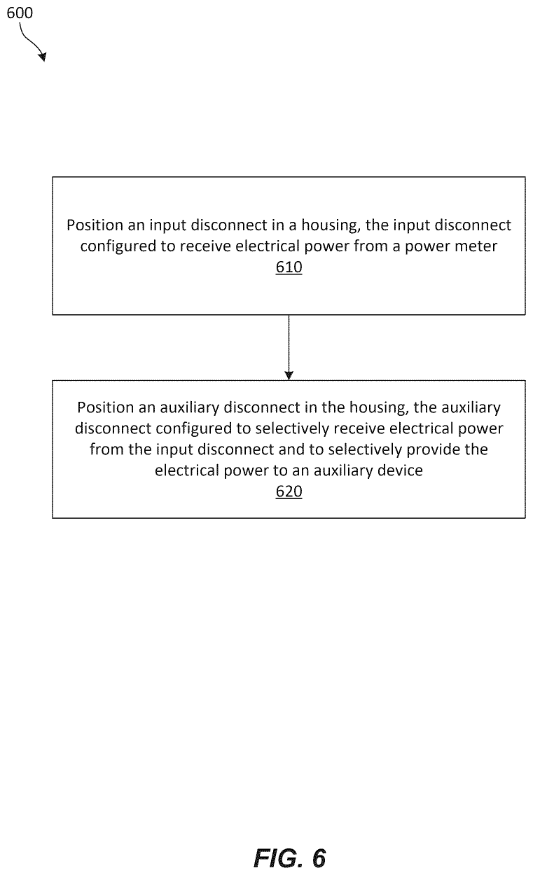

FIG. 6 is a flow diagram illustrating a method 600 of forming a power supply system, according to at least one embodiment of the present disclosure.

At operation 610, an input disconnect may be positioned in a housing. The input disconnect may be configured to receive electrical power from a power meter.

At operation 620, an auxiliary disconnect may be positioned in the housing. The auxiliary disconnect may be configured to selectively receive electrical power from the input disconnect and to selectively provide the electrical power to an auxiliary device.

In some examples, the method 600 may also include positioning an electrical monitoring device in the auxiliary connection section. The electrical monitoring device may include at least one of: a main current sensor for sensing electrical current passing from the input disconnect to a main disconnect panel, and/or an auxiliary current sensor for sensing electrical current passing from the auxiliary disconnect to an auxiliary device.

Accordingly, the present disclosure includes devices, systems, and methods for electrical power supplies. Some embodiments may employ an auxiliary connection device with a housing that is separate from a meter socket for containing a power meter. The auxiliary connection device may enable a user or technician to connect one or more auxiliary devices to the electrical power supply.

The following example embodiments are also included in the present disclosure.

Example 1. An electrical power supply system, comprising: a housing separate from a meter socket; an input disconnect in the housing configured to receive electrical power from the meter socket; an auxiliary disconnect in the housing configured to receive electrical power from the input disconnect and to provide the electrical power to an auxiliary device; and a main electrical output in the housing configured to receive electrical power from the input disconnect and to provide the electrical power to a disconnect panel.

Example 2. The system of Example 1, further comprising an auxiliary electrical output configured to receive electrical power from the auxiliary disconnect and to provide the electrical power to the auxiliary device.

Example 3. The system of Example 2, further comprising an electrical monitoring device in the housing, the electrical monitoring device configured to sense electrical current passing through at least one of the main electrical output or the auxiliary electrical output.

Example 4. The system of Example 3, wherein the electrical monitoring device comprises at least one of: an input current sensor coupled to the input disconnect to sense electrical current passing into the housing; a main current sensor coupled to the main electrical output to sense electrical current passing through the main electrical output; or an auxiliary current sensor coupled to the auxiliary electrical output to sense electrical current passing through the auxiliary electrical output.

Example 5. The system of Example 4, wherein the main electrical output comprises a main conductor and the auxiliary electrical output comprises an auxiliary conductor.

Example 6. The system of any one of Examples 2 through 5, further comprising at least one auxiliary lug that splits a conductive path from the input disconnect into the main electrical output and the auxiliary electrical output.

Example 7. The system of any one of Examples 1 through 6, further comprising a neutral lug in the housing, the neutral lug configured to be coupled to a neutral wire.

Example 8. The system of any one of Examples 1 through 7, further comprising a ground lug in the housing, the ground lug configured to be coupled to a ground wire.

Example 9. The system of any one of Examples 1 through 8, wherein the auxiliary device comprises one or more of: an electric vehicle charging station; an electric vehicle; a pump; an air conditioning unit; a heater; or a refrigerator.

Example 10. The system of any one of Examples 1 through 9, wherein the disconnect panel comprises one or more of: a residential breaker panel; a commercial breaker panel; a fuse box; a fusible switch box; or a protective relay panel.

Example 11. The system of any one of Examples 1 through 10, wherein: the input disconnect comprises an input breaker; and the auxiliary disconnect comprises an auxiliary breaker.

Example 12. An electrical power supply system, comprising: a meter socket including a socket for connecting a power meter; a housing separate from the meter socket; an input disconnect in the housing; an inlet branch in the housing for providing electrical power from the meter socket to the input disconnect; a main outlet branch in the housing for selectively transmitting electrical power from the input disconnect to a main disconnect panel; an auxiliary outlet branch in the housing for selectively transmitting electrical power from the input disconnect to an auxiliary device; and at least one auxiliary disconnect in the housing and coupled to the auxiliary outlet branch, the at least one auxiliary disconnect configured to selectively transmit electrical power respectively to at least one auxiliary device.

Example 13. The system of Example 12, wherein the input disconnect comprises at least one of: an input fuse; an input breaker; an input fusible switch; or an input protective relay.

Example 14. The system of Example 12 or Example 13, wherein the at least one auxiliary disconnect comprises at least one of: an auxiliary fuse; an auxiliary breaker; an auxiliary fusible switch; or an auxiliary protective relay.

Example 15. The system of any one of Examples 12 through 14, further comprising an electrical monitoring device in the housing, the electrical monitoring device comprising: at least one input current sensor configured to sense electrical current passing from the meter socket to the input disconnect along the inlet branch; at least one main current sensor configured to sense electrical current passing to the main disconnect panel from the input disconnect along the main outlet branch; and at least one auxiliary current sensor configured to sense electrical current passing to the at least one auxiliary device from the at least one auxiliary disconnect through the auxiliary outlet branch.

Example 16. The system of Example 15, further comprising a communication module for communicating information based on signals from the at least one input current sensor, at least one main current sensor, and at least one auxiliary current sensor to a user device.

Example 17. The system of Example 16, wherein the at least one auxiliary disconnect comprises at two or more auxiliary disconnects configured to selectively transmit electrical power respectively to two or more auxiliary devices.

Example 18. The system of any one of Examples 12 through 17, wherein the housing is mounted adjacent to and along a same wall as the meter socket.

Example 19. A method of forming a power supply system, the method comprising: positioning an input disconnect in a housing, the input disconnect configured to receive electrical power from a power meter; and positioning an auxiliary disconnect in the housing, the auxiliary disconnect configured to selectively receive electrical power from the input disconnect and to selectively provide the electrical power to an auxiliary device.

Example 20. The method of Example 19, further comprising positioning an electrical monitoring device in the housing, the electrical monitoring device including a main current sensor for sensing electrical current passing from the input disconnect to a main disconnect panel and an auxiliary current sensor for sensing electrical current passing from the auxiliary disconnect to an auxiliary device.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed.

The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An electrical power supply system, comprising:
a housing separate from a meter socket;
an input disconnect in the housing configured to receive electrical power from the meter socket;
an auxiliary disconnect in the housing configured to receive electrical power from the input disconnect and to provide the electrical power to an auxiliary device; and
a main electrical output in the housing configured to receive electrical power from the input disconnect and to provide the electrical power to a disconnect panel.

2. The system of claim 1, further comprising an auxiliary electrical output configured to receive electrical power from the auxiliary disconnect and to provide the electrical power to the auxiliary device.

3. The system of claim 2, further comprising an electrical monitoring device in the housing, the electrical monitoring device configured to sense electrical current passing through at least one of the main electrical output or the auxiliary electrical output.

4. The system of claim 3, wherein the electrical monitoring device comprises at least one of:
an input current sensor coupled to the input disconnect to sense electrical current passing into the housing;
a main current sensor coupled to the main electrical output to sense electrical current passing through the main electrical output; or
an auxiliary current sensor coupled to the auxiliary electrical output to sense electrical current passing through the auxiliary electrical output.

5. The system of claim 4, wherein the main electrical output comprises a main conductor and the auxiliary electrical output comprises an auxiliary conductor.

6. The system of claim 2, further comprising at least one auxiliary lug that splits a conductive path from the input disconnect into the main electrical output and the auxiliary electrical output.

7. The system of claim 1, further comprising a neutral lug in the housing, the neutral lug configured to be coupled to a neutral wire.

8. The system of claim 1, further comprising a ground lug in the housing, the ground lug configured to be coupled to a ground wire.

9. The system of claim 1, wherein the auxiliary device comprises one or more of:
an electric vehicle charging station;
an electric vehicle;
a pump;
an air conditioning unit;
a heater; or
a refrigerator.

10. The system of claim 1, wherein the disconnect panel comprises one or more of:
a residential breaker panel;
a commercial breaker panel;
a fuse box;
a fusible switch box; or
a protective relay panel.

11. The system of claim 1, wherein:
the input disconnect comprises an input breaker; and
the auxiliary disconnect comprises an auxiliary breaker.

12. An electrical power supply system, comprising:
a meter socket including a socket for connecting a power meter;
a housing separate from the meter socket;
an input disconnect in the housing;
an inlet branch in the housing for providing electrical power from the meter socket to the input disconnect;
a main outlet branch in the housing for selectively transmitting electrical power from the input disconnect to a main disconnect panel;
an auxiliary outlet branch in the housing for selectively transmitting electrical power from the input disconnect to an auxiliary device; and
at least one auxiliary disconnect in the housing and coupled to the auxiliary outlet branch, the at least one auxiliary disconnect configured to selectively transmit electrical power respectively to at least one auxiliary device.

13. The system of claim 12, wherein the input disconnect comprises at least one of:
an input fuse;
an input breaker;
an input fusible switch; or
an input protective relay.

14. The system of claim 12, wherein the at least one auxiliary disconnect comprises at least one of:
an auxiliary fuse;
an auxiliary breaker;
an auxiliary fusible switch; or
an auxiliary protective relay.

15. The system of claim 12, further comprising an electrical monitoring device in the housing, the electrical monitoring device comprising:
at least one input current sensor configured to sense electrical current passing from the meter socket to the input disconnect along the inlet branch;
at least one main current sensor configured to sense electrical current passing to the main disconnect panel from the input disconnect along the main outlet branch; and
at least one auxiliary current sensor configured to sense electrical current passing to the at least one auxiliary device from the at least one auxiliary disconnect through the auxiliary outlet branch.

16. The system of claim 15, further comprising a communication module for communicating information based on signals from the at least one input current sensor, at least one main current sensor, and at least one auxiliary current sensor to a user device.

17. The system of claim 16, wherein the at least one auxiliary disconnect comprises at two or more auxiliary disconnects configured to selectively transmit electrical power respectively to two or more auxiliary devices.

18. The system of claim 12, wherein the housing is mounted adjacent to and along a same wall as the meter socket.

19. A method of forming a power supply system, the method comprising:
positioning an input disconnect in a housing, the input disconnect configured to receive electrical power from a power meter; and
positioning an auxiliary disconnect in the housing, the auxiliary disconnect configured to selectively receive electrical power from the input disconnect and to selectively provide the electrical power to an auxiliary device.

20. The method of claim 19, further comprising positioning an electrical monitoring device in the housing, the electrical monitoring device including a main current sensor for sensing electrical current passing from the input disconnect to a main disconnect panel and an auxiliary current sensor for sensing electrical current passing from the auxiliary disconnect to an auxiliary device.
